(19) United States
(12) Patent Application Publication
(10) Pub. No.: US 2024/0304461 A1
(43) Pub. Date: Sep. 12, 2024

(54) CERAMIC SUBMOUNT FOR SEMICONDUCTOR DEVICE AND METHOD FOR MANUFACTURING THE SAME

(71) Applicant: TONG HSING ELECTRONIC INDUSTRIES, LTD., Taipei City (TW)

(72) Inventors: CHENG-HUNG SHEN, Taipei City (TW); SHIH-HAN WU, Taipei City (TW); JHIH-WEI LAI, Taipei City (TW); JIAN-YU SHIH, Taipei City (TW); MING-YEN PAN, Taipei City (TW); CHIA-SHUAI CHANG, Hsin-Chu County (TW)

(21) Appl. No.: 18/396,618

(22) Filed: Dec. 26, 2023

Related U.S. Application Data
(60) Provisional application No. 63/450,405, filed on Mar. 7, 2023.

(30) Foreign Application Priority Data
Oct. 3, 2023 (TW) 112137798

(51) Int. Cl. H01L 21/48; H01L 23/15; H01L 23/498

(52) U.S. Cl. CPC H01L 21/4853; H01L 23/15; H01L 23/49811

(57) ABSTRACT

A ceramic submount for a semiconductor device and a method for manufacturing the same are provided. The ceramic submount includes a ceramic core board, an electrode layer, and a solder unit. The electrode layer is disposed on one side of the ceramic core board. The solder unit includes a buffer containing layer and a soldering layer. A cross-section of the solder unit has an inversed-trapezoid shape. The buffer containing layer is disposed on a surface of the electrode layer. A receiving space is concavely formed on a top surface of the buffer containing layer, and the soldering layer is filled in the receiving space. The buffer containing layer surrounds the soldering layer.

### CROSS-REFERENCE TO RELATED PATENT APPLICATION

This application claims the benefit of priorities to the U.S. Provisional Patent Application Ser. No. 63/450,405, filed on Mar. 7, 2023, and Taiwan Patent Application No. 112137798, filed on Oct. 3, 2023. The entire content of each of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a ceramic submount for a semiconductor device and a method for manufacturing the same, and more particularly to a ceramic submount on which a semiconductor chip (e.g., a light emitting diode die or a laser diode die) can be bonded as a chip-on-submount.

### BACKGROUND OF THE DISCLOSURE

A conventional packaging process of an LED or a laser diode is to mount a semiconductor die (e.g., an LED die or a laser diode die) on a submount. The submount can be referred to as a ceramic submount or a cooling submount. The main function of the ceramic submount is to quickly conduct heat generated by the die away from the die, so as to prevent deterioration of the die.

The submount has a bonding zone onto which the semiconductor die can be bonded. A eutectic layer is formed on the bonding zone, and an area of the eutectic layer is smaller than or equal to an area of the submount. The material of the eutectic layer of the submount can be an AuSn alloy.

In a bonding process of the semiconductor die, the die is first placed on the eutectic layer of the bonding zone, and is heated to a melting point of the eutectic layer before cooling, so that the die and the submount can be tightly bonded. After being cooled, the submount is divided by partition regions to form individual LED or laser diode packages.

Conventionally, a conductive portion of the submount has a rectangular planar shape. During the above-mentioned heating and melting process, the AuSn alloy of the eutectic layer may spread outward to a gold surface of a non-bonding zone, and react in the non-bonding zone, thereby resulting in an intermetallic compound phenomenon.

### SUMMARY OF THE DISCLOSURE

In response to the above-referenced technical inadequacies, the present disclosure provides a ceramic submount for a semiconductor device, so as to avoid occurrence of an intermetallic compound phenomenon during a heating process for bonding a semiconductor chip.

In order to solve the above-mentioned problems, one of the technical aspects adopted by the present disclosure is to provide a ceramic submount for a semiconductor device. The ceramic submount includes a ceramic core board, an electrode layer, and a solder unit. The electrode layer is disposed on one side of the ceramic core board. The solder unit includes a buffer containing layer and a soldering layer. A cross-section of the solder unit has an inversed-trapezoid shape. The buffer containing layer is disposed on a surface of the electrode layer. A receiving space is concavely formed on a top end of the buffer containing layer. The soldering layer is filled in the receiving space. The buffer containing layer surrounds the soldering layer.

In order to solve the above-mentioned problems, another one of the technical aspects adopted by the present disclosure is to provide a method for manufacturing a ceramic submount, which includes processes of: providing a ceramic core board; forming an electrode layer on a side of the ceramic core board; forming a buffer containing layer on a surface of the electrode layer, in which a receiving space is concavely formed on a top surface of the buffer containing layer; and filling a soldering layer in the receiving space of the buffer containing layer. The buffer containing layer and the soldering layer is configured as a solder unit, and a cross-section of the solder unit has an inversed-trapezoid shape.

Therefore, in the ceramic submount for the semiconductor device and the method for manufacturing the same provided by the present disclosure, during the heating process for bonding the semiconductor chip to the ceramic submount, the buffer containing layer is shaped as a bowl, and the melted soldering layer will not spread out to the electrode layer for being surrounded and restricted in the buffer containing layer. In this way, the intermetallic compound phenomenon can be effectively prevented.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A to FIG. 1H and FIG. 1J are schematic views illustrating processes for manufacturing a ceramic submount for a semiconductor device according to the present disclosure;

FIG. 2 is a schematic cross-sectional view of the ceramic submount for the semiconductor device according to a first embodiment of the present disclosure;

FIG. 3 is a schematic perspective view of the ceramic submount for the semiconductor device according to the first embodiment of the present disclosure;

FIG. 4 is a schematic cross-sectional view of the ceramic submount for the semiconductor device according to a second embodiment of the present disclosure; and

FIG. 5 is a schematic cross-sectional view of the ceramic submount for the semiconductor device according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

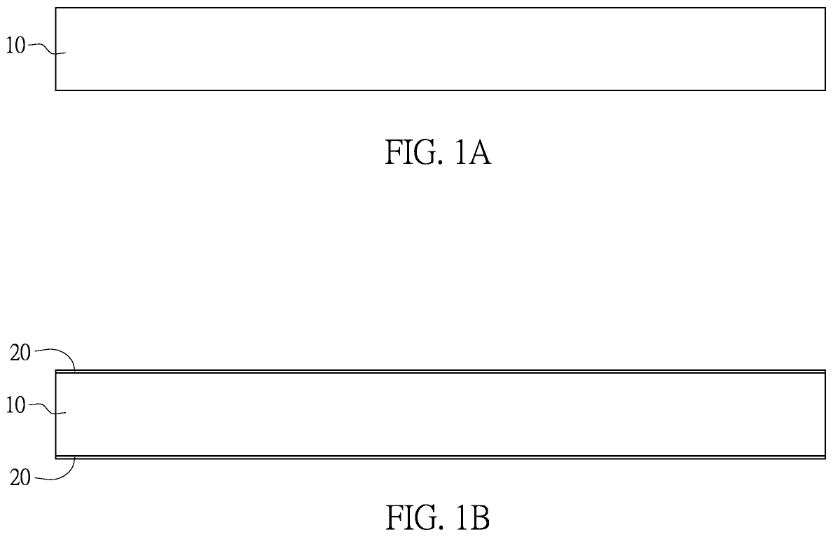

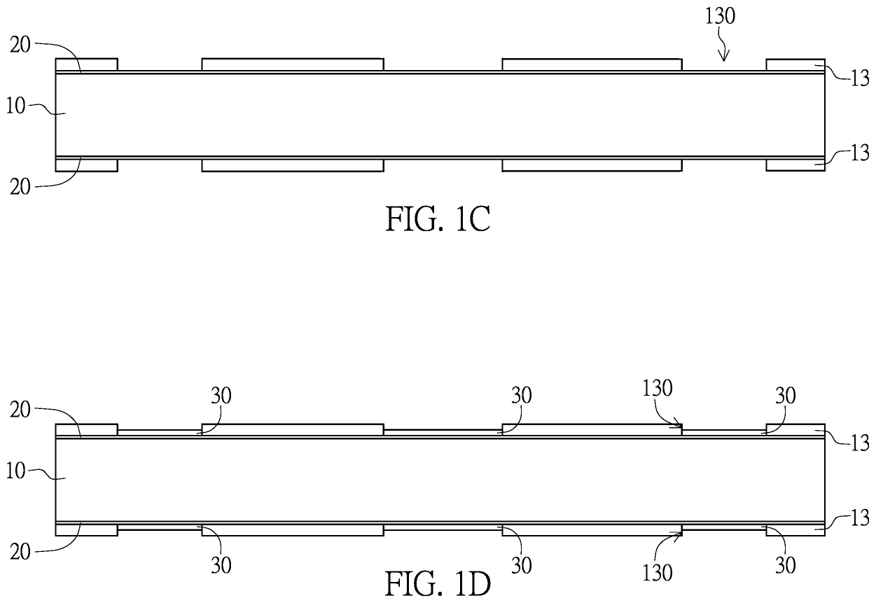

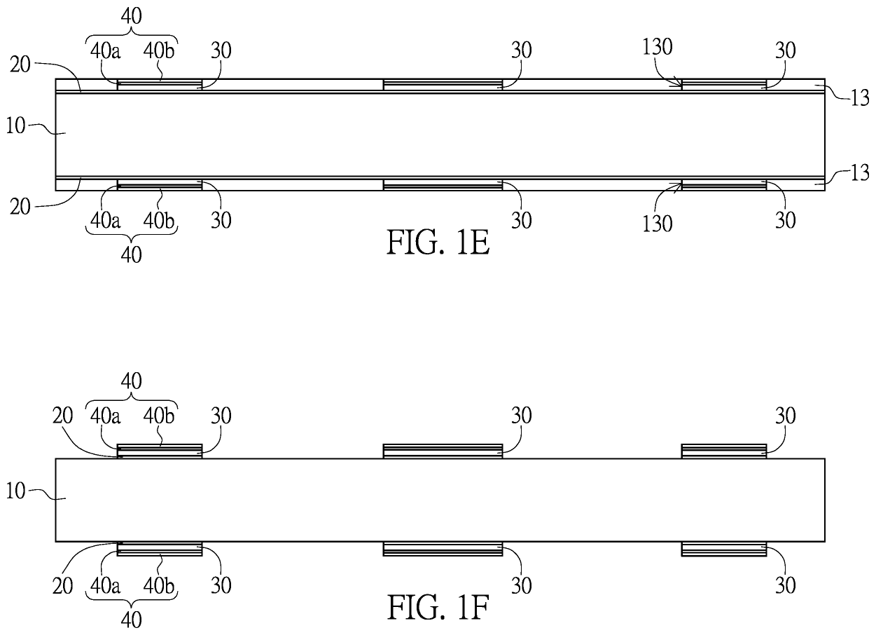

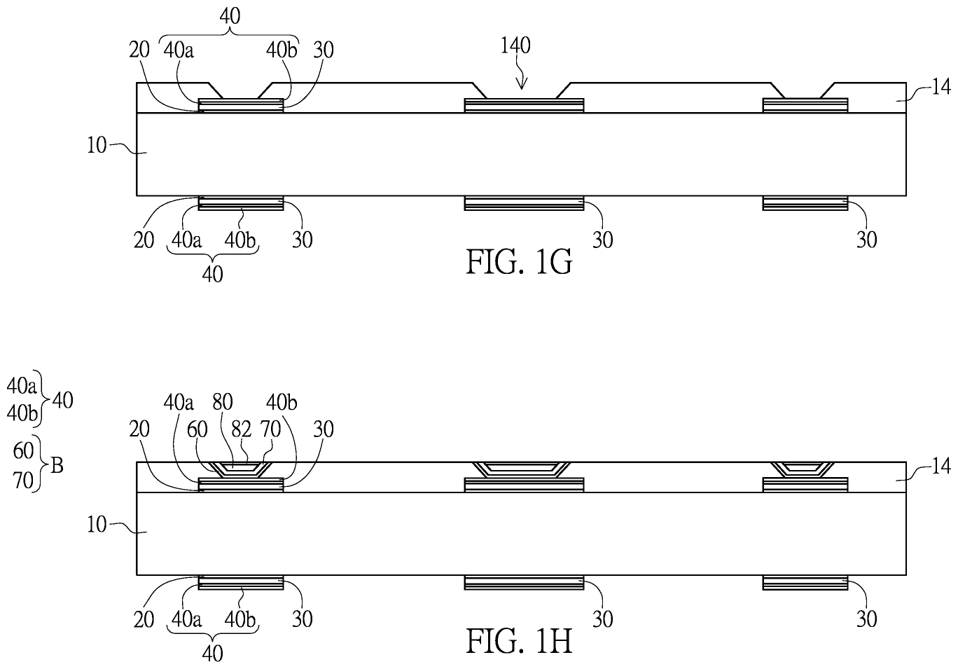

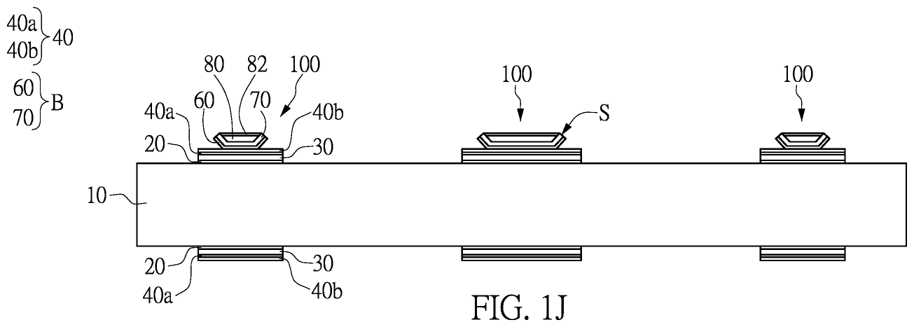

Referring to FIG. 1A to FIG. 1H, a first embodiment of the present disclosure provides a method for manufacturing a ceramic submount for a semiconductor device. The ceramic submount of this embodiment can also be referred to as a submount or a heat-dissipating submount. The method includes processes as follows.

Referring to FIG. 1A, a ceramic core board 10 is provided as a substrate. The ceramic core board 10 can be made of aluminum nitride (AlN). However, the present disclosure is not limited thereto. The ceramic core board 10 can also be made of aluminum oxide (Al₂O₃), silicon carbide (SiC), or silicon nitride (Si₃N₄).

Referring to FIG. 1B, a seed layer 20 is disposed on an upper surface of the ceramic core board 10 through a sputtering process. In the present embodiment, the seed layer 20 is made of titanium (Ti), and is formed on the upper surface and a lower surface of the ceramic core board 10. The function of the seed layer 20 is used to tightly contact with a surface of the ceramic core board 10. However, the present disclosure is not limited thereto. The seed layer 20 can also be made of chromium (Cr), nichrome (NiCr), tantalum (Ta), or a compound thereof.

Referring to FIG. 1C, a first peelable layer 13 is disposed on a surface of the seed layer 20. In the present embodiment, the first peelable layer 13 can be, for example, a dry film photoresist, and a predetermined first pattern trench 130 is formed through a photolithography process. In the present embodiment, a small pattern corresponds to a region of a semiconductor die on the submount. For example, the submount can be formed with a plurality of grids. Taking the dry film photoresist as an example, a photo-sensitive resist is applied in a laminated manner to form photoresist layers on the surface of the seed layer 20. After lamination, an exposure process (pattern exposure) is performed by using a mask, and an exposure target portion of the photoresist layer is selectively irradiated. Then, the photoresist pattern is developed by, for example, adding a developer, so as to show a first pattern. Afterwards, the first peelable layer 13 is etched to form a first pattern trench 130.

Referring to FIG. 1D, at least one protective layer 30 is formed on the first pattern trench 130. In this embodiment, the at least one protective layer 30 includes a copper protective layer. The copper protective layer is formed on the seed layer 20. Specifically, the copper protective layer can be formed on the golden seed layer 20 by an electroplating process, and is subjected to a grinding process.

Referring to FIG. 1E, an electrode layer 40 is formed on one side of the ceramic core board 10. Specifically, the electrode layer 40 is formed on the at least one protective layer 30. The electrode layer 40 can include a nickel plating layer 40a and a gold capping layer 40b, each of which is formed by an electroless nickel immersion gold process. The nickel plating layer 40a is formed on the copper protective layer. The gold capping layer 40b covers an outer surface of the nickel plating layer 40a. In addition, the first pattern trench 130 corresponds in shape to the protective layer 30 and the electrode layer 40. Lateral sides of the first pattern trench 130 can be perpendicular to the surface of the ceramic core board 10, and can have, for example, a rectangular shape or a disk shape.

Referring to FIG. 1F, the first peelable layer 13 is removed. For example, the dry film photoresist can be removed by a solvent. In addition, the seed layer 20 that is exposed to the surface of the ceramic core board 10 is removed. After this process is completed, a partial surface of the ceramic core board 10 is exposed to the outside.

Referring to FIG. 1G, a second peelable layer 14 is formed on the electrode layer 40. The second peelable layer 14 also covers a portion of the exposed surface of the ceramic core board 10. A critical step of this embodiment is that, the second peelable layer 14 is etched to form a bowl-shaped concave portion 140. The electrode layer 40 is exposed to a bottom portion of the bowl-shaped concave portion 140. In the present embodiment, a cross-section of the bowl-shaped concave portion 140 has an inversed-trapezoid shape. In other words, outer sides of the bowl-shaped concave portion 140 are inclined related to the electrode layer 40. From its bottom portion, the bowl-shaped concave portion 140 is gradually enlarged in an outward manner. Specifically, an area of the bottom portion of the bowl-shaped concave portion 140 is smaller than an area of a top opening thereof. The top opening of the bowl-shaped concave portion 140 is located at an outer surface of the second peelable layer 14.

The second peelable layer 14 of the present embodiment can be a liquid photoresist. Specifically, a liquid photoresist ink is coated onto the electrode layer 40. The advantage of the liquid photoresist is that, a thickness of a coating layer can be measured when a coating material is in a wet film state, such that the accuracy of the thickness can be ensured. In the present embodiment, the second peelable layer 14 is etched by a photolithography process, so as to form the bowl-shaped concave portion 140. In addition, in the present embodiment, a thickness of the liquid photoresist is larger than a thickness of the dry film photoresist.

Referring to FIG. 1H, a buffer containing layer B is formed on an inner surface of the bowl-shaped concave portion 140, and a receiving space B1 is concavely formed on a top surface of the buffer containing layer B. The buffer containing layer B is located on a surface of the electrode layer 40.

Next, a soldering layer 80 is filled in the receiving space B1 of the buffer containing layer B. The buffer containing layer B and the soldering layer 80 are configured as a solder unit S. The solder unit S is formed in an inversed-trapezoid shape in a crossed-sectional view. Specifically, in the present embodiment, the soldering layer 80 can be filled by an evaporation process in the receiving space B1 of the buffer containing layer B.

Preferably, a solder resist layer 82 is disposed on the soldering layer 80. The solder resist layer 82 is used to protect the soldering layer 80. The solder resist layer 82 can be made of gold (Au), so that the soldering layer 80 forms an Au—Sn alloy.

Furthermore, a top surface of the soldering layer 80 can be polished, so as to connect to a semiconductor chip. In the present embodiment, the solder resist layer 82 is polished, which is beneficial for connecting a gold wire to the semiconductor chip.

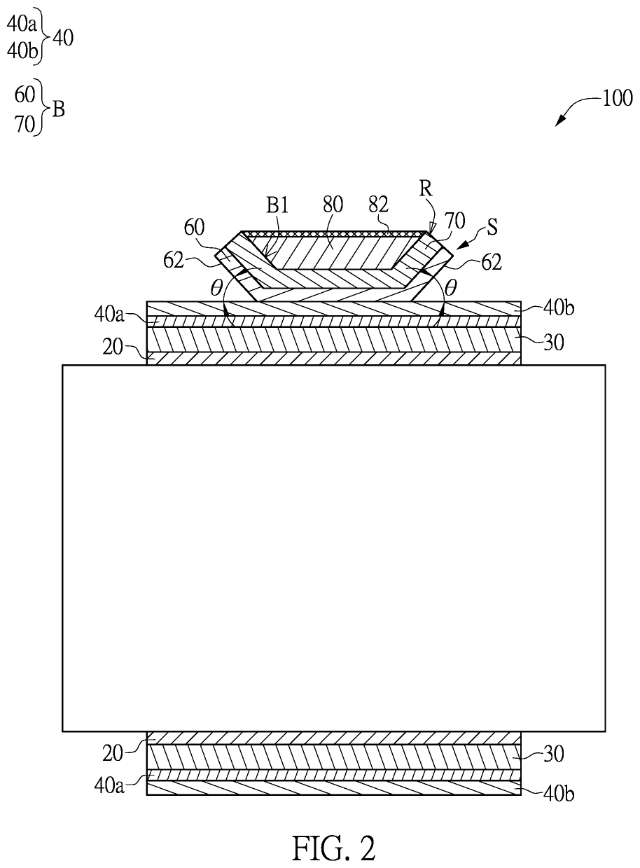

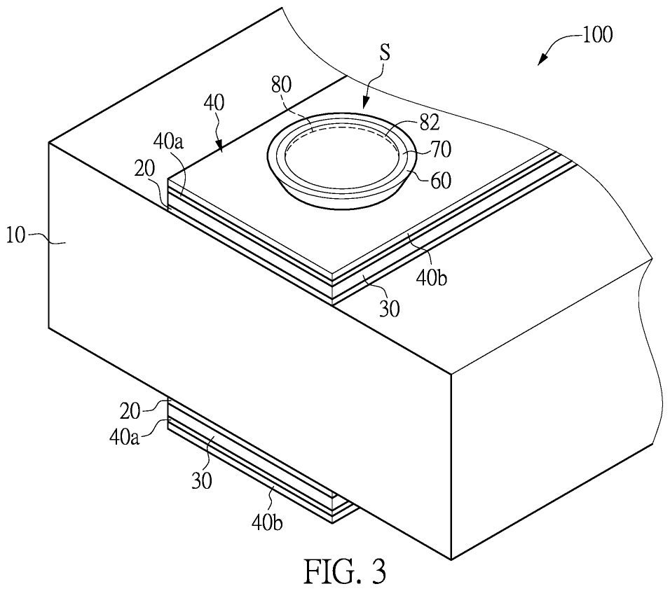

Referring to FIG. 2 and FIG. 3, FIG. 3 is a schematic perspective view of a ceramic submount 100 according to an embodiment of the present disclosure. Specifically, the buffer containing layer B includes at least one buffer layer (which is made of metal). In the present embodiment, the buffer containing layer B includes a first buffer layer 60 and a second buffer layer 70. The first buffer layer 60 is bowl-shaped and contacts the electrode layer 40. The second buffer layer 70 is bowl-shaped, and is formed on an inner surface of the first buffer layer 60. The soldering layer 80 is filled in an interior of the second buffer layer 70. In the present embodiment, the first buffer layer 60 contains titanium (Ti), the second buffer layer 70 contains platinum (Pt), and the soldering layer 80 contains tin (Sn).

In another practical embodiment of the present disclosure, the buffer containing layer B only includes one buffer layer. For example, the second buffer layer 70 that contains platinum (Pt) is included, and the first buffer layer 60 is omitted. In the present embodiment, a titanium (Ti) buffer layer is omittable.

Referring to FIG. 1J, the second peelable layer 14 is removed. For example, the liquid photoresist can be removed by the solvent.

In addition, another seed layer 20, another protective layer 30, and another electrode layer 40 can be formed on the other side of the ceramic core board 10. In detail, the another seed layer 20 is formed on a lower surface of the ceramic core board 10, and corresponds in position to the solder unit S. The another protective layer 30 is formed on an upper surface of the another seed layer 20. The another electrode layer 40 is formed on the another protective layer 30.

Reference is made to FIG. 2, which is a schematic cross-sectional view of the finished ceramic submount for the semiconductor device. Through the above-mentioned method, the ceramic submount 100 for the semiconductor device of the present embodiment at least includes the ceramic core board 10, the seed layer 20, the protective layer 30, the electrode layer 40, and the solder unit S. The electrode layer 40 is formed at one side of the ceramic core board 10. The solder unit S includes the buffer containing layer B and the soldering layer 80. The solder unit S is formed in an inversed-trapezoid shape in a crossed-sectional view. The buffer containing layer B is disposed on the surface of the electrode layer 40. The receiving space B1 is concavely formed on the top surface of the buffer containing layer B. The soldering layer 80 is filled in the receiving space B1. The buffer containing layer B surrounds the soldering layer 80.

Referring to FIG. 2, the first buffer layer 60 has two outer sides 62 that are each planar-shaped. Each of the outer sides 62 is inclined related to the electrode layer 40. An acute angle 9 is formed between each of the outer sides 62 and the electrode layer 40.

Therefore, in the present embodiment, during a heating process for bonding the semiconductor chip, the buffer containing layer B is bowl-shaped, and the melted soldering layer 80 will not spread out to the electrode layer 40 for being surrounded and restricted in the buffer containing layer B. In this way, an intermetallic compound phenomenon can be effectively prevented.

It is worth mentioning that, in this embodiment, a periphery of a top edge of the solder unit S has a chamfer R, and a radius of the chamfer R is smaller than 10 μm. In other words, when titanium (Ti) of the first buffer layer 60, platinum (Pt) of the second buffer layer 70, and the Au—Sn alloy of the soldering layer 80 are subjected to evaporation, a conductive sidewall angle that is almost vertical can be formed, such that the risk of shielding a laser light can be reduced.

### Second Embodiment

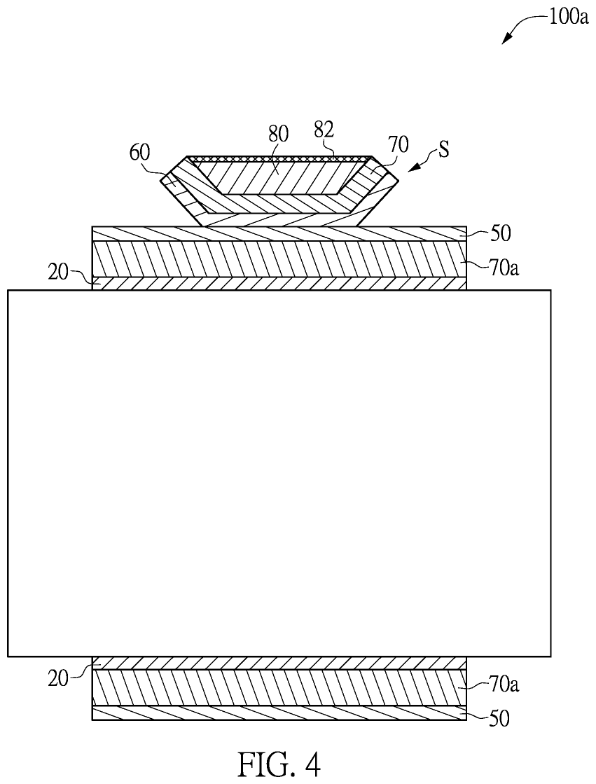

Referring to FIG. 4, a second embodiment of the present disclosure provides a ceramic submount 100a for a semiconductor device. The main difference between the first and second embodiments is as follows. In the second embodiment, a protective layer 70a and an electrode layer 50 are disposed between the solder unit S and the seed layer 20. The protective layer 70a includes a platinum (Pt) protective layer. The electrode layer 50 can be gold, and is formed on the platinum (Pt) protective layer. The advantage is that the quantity of metal layers between the solder unit S and the seed layer 20 can be reduced.

### Third Embodiment

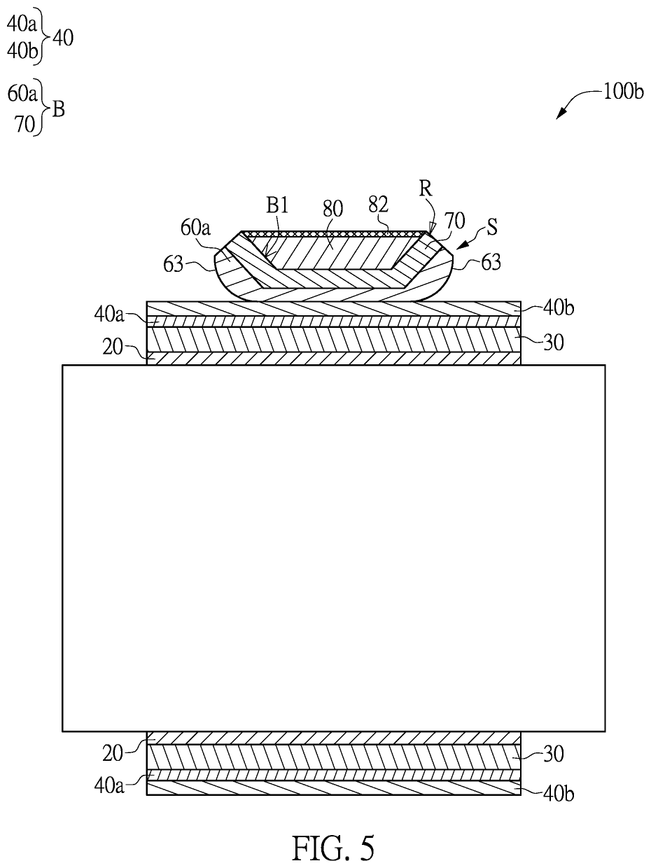

Referring to FIG. 5, this embodiment provides a ceramic submount 100b for a semiconductor device. The difference between this embodiment and the above-mentioned embodiments is that, a first buffer layer 60a has two outer sides 63 that are each arc-shaped. Arc-shaped outer sides can also be applied to the second embodiment.

### Beneficial Effects of the Embodiments

In conclusion, in the ceramic submount for the semiconductor device and the method for manufacturing the same provided by the present disclosure, during the heating process for bonding the semiconductor chip to the ceramic submount, the buffer containing layer is shaped as a bowl, and the melted soldering layer will not spread out to the electrode layer for being surrounded and restricted in the buffer containing layer. In this way, the intermetallic compound phenomenon can be effectively prevented.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A ceramic submount for a semiconductor device, comprising:
a ceramic core board;
an electrode layer disposed on one side of the ceramic core board; and
a solder unit including a buffer containing layer and a soldering layer, wherein a cross-section of the solder unit has an inversed-trapezoid shape, the buffer containing layer is disposed on a surface of the electrode layer, a receiving space is concavely formed on a top surface of the buffer containing layer, the soldering layer is filled in the receiving space, and the buffer containing layer surrounds the soldering layer.

2. The ceramic submount according to claim 1, further comprising a seed layer and at least one protective layer disposed between the electrode layer and the solder unit, wherein the seed layer is formed on an upper surface of the ceramic core board, the at least one protective layer is formed on an upper surface of the seed layer, and the electrode layer is formed on the at least one protective layer.

3. The ceramic submount according to claim 2, wherein the seed layer contains titanium and tightly contacts with the ceramic core board, the at least one protective layer includes a copper protective layer, the copper protective layer is formed on the seed layer, the electrode layer includes a nickel plating layer and a gold capping layer in an electroless nickel immersion gold process, and the gold capping layer covers an outer surface of the nickel plating layer.

4. The ceramic submount according to claim 2, wherein the seed layer contains titanium and tightly contacts with the ceramic core board, and the at least one protective layer includes a platinum protective layer.

5. The ceramic submount according to claim 1, wherein the buffer containing layer includes a first buffer layer and a second buffer layer, the first buffer layer is bowl-shaped and contacts the electrode layer, the second buffer layer is bowl-shaped and is formed on an inner surface of the first buffer layer, and the soldering layer is filled in the second buffer layer.

6. The ceramic submount according to claim 5, wherein the first buffer layer contains titanium, the second buffer layer contains platinum, and the soldering layer includes a gold-tin alloy material.

7. The ceramic submount according to claim 5, wherein the first buffer layer has two outer sides, the two outer sides are each planar shaped, each of the outer sides is inclined relative to the electrode layer, and an acute angle is formed between each of the outer sides and the electrode layer.

8. The ceramic submount according to claim 5, wherein the first buffer layer has two outer sides, and the two outer sides are each arc-shaped.

9. The ceramic submount according to claim 1, wherein a periphery of a top edge of the solder unit has a chamfer, and a radius of the chamfer is smaller than 10 μm.

10. The ceramic submount according to claim 2, wherein another seed layer, another protective layer, and another electrode layer are formed on another side of the ceramic core board, the another seed layer corresponds in position to the solder unit, the another protective layer is formed on an upper surface of the another seed layer, and the another electrode layer is formed on the another protective layer.

11. The ceramic submount according to claim 1, wherein the buffer containing layer includes at least one buffer layer, the at least one buffer layer is bowl-shaped and contacts the electrode layer, and the soldering layer is filled in the at least one buffer layer; wherein the at least one buffer layer contains platinum.

12. A method for manufacturing a ceramic submount, comprising:
providing a ceramic core board;
forming an electrode layer on a side of the ceramic core board;
forming a buffer containing layer on a surface of the electrode layer, wherein a receiving space is concavely formed on a top surface of the buffer containing layer; and
filling a soldering layer in the receiving space of the buffer containing layer;
wherein the buffer containing layer and the soldering layer are configured as a solder unit, and a cross-section of the solder unit has an inversed-trapezoid shape.

13. The method according to claim 12, further comprising:
sputtering a seed layer on an upper surface of the ceramic core board;
forming a first peelable layer on a surface of the seed layer;
etching the first peelable layer to form a first pattern trench;
forming at least one protective layer in the first pattern trench;
forming the electrode layer on the at least one protective layer;
removing the first peelable layer and a portion of the seed layer;
forming a second peelable layer on the electrode layer;
etching the second peelable layer to form a bowl-shaped concave portion, wherein the electrode layer is exposed to a bottom portion of the bowl-shaped concave portion;
forming a buffer containing layer in an inner surface of the bowl-shaped concave portion, and forming the receiving space;
filling the soldering layer in the receiving space of the buffer containing layer; and
removing the second peelable layer.

14. The method according to claim 13, wherein the first peelable layer is a dry film photoresist, the second peelable layer is a liquid photoresist, and a thickness of the liquid photoresist is larger than a thickness of the dry film photoresist.

15. The method according to claim 14, further comprising:
etching the first peelable layer by a photolithography process, so as to form the first pattern trench.

16. The method according to claim 15, further comprising:
etching the second peelable layer by the photolithography process, so as to form the bowl-shaped concave portion.

17. The method according to claim 13, wherein an area of the bottom portion of the bowl-shaped concave portion is smaller than an area of a top opening of the bowl-shaped concave portion.

18. The method according to claim 12, further comprising:
filling the soldering layer in the receiving space of the buffer containing layer by an evaporation process.

19. The method according to claim 18, further comprising:
forming a solder resist layer on the soldering layer, wherein the solder resist layer is configured to protect the soldering layer, and the solder resist layer contains gold.
